(19) United States
(12) Patent Application Publication
(10) Pub. No.: US 2026/0271333 A1
(43) Pub. Date: Sep. 10, 2026

(54) SEMICONDUCTOR DEVICE

(71) Applicant: Murata Manufacturing Co., Ltd., Kyoto-fu (JP)

(72) Inventors: Mari SAJI, Nagaokakyo-shi (JP); Akira FUJIHARA, Nagaokakyo-shi (JP)

(73) Assignee: Murata Manufacturing Co., Ltd., Kyoto-fu (JP)

(21) Appl. No.: 19/674,660

(22) Filed: May 12, 2026

Related U.S. Application Data
(63) Continuation of application No. PCT/JP2024/027015, filed on Jul. 29, 2024.

(30) Foreign Application Priority Data
Nov. 24, 2023 (JP) 2023-199063

(51) Int. Cl. H10D 30/65; H10D 30/01; H10D 62/10; H10D 64/00; H10W 20/41; H10W 20/43

(52) U.S. Cl. CPC H10D 30/655; H10D 30/657; H10D 62/102; H10D 62/124; H10D 64/111; H10D 30/0281; H10D 64/112; H10W 20/43; H10W 20/435

(57) ABSTRACT

A field-effect transistor is on an insulating surface, and an interlayer insulator film covers the field-effect transistor. An electroconductive field plate is on the interlayer insulator film. The field-effect transistor includes a source region with first electroconductivity, a body region with second electroconductivity, a drift region with the first electroconductivity, a drain region with the first electroconductivity, and a gate electrode. When the insulating surface is viewed in plan, the gate electrode has a shape elongated in a first direction, and the body region is below the gate electrode to overlap the gate electrode. The source region and the drift region are at positions to hold the body region therebetween in a second direction orthogonal to the first direction, and the drain region is at a position farther than the drift region is when viewed from the body region.

### CROSS-REFERENCE TO RELATED APPLICATIONS

This application claims benefit of priority to International Patent Application No. PCT/JP2024/027015, filed Jul. 29, 2024, and to Japanese Patent Application No. 2023-199063, filed Nov. 24, 2023, the entire contents of each are incorporated herein by reference.

### BACKGROUND

### Technical Field

The present disclosure relates to a semiconductor device.

### Background Art

A field-effect transistor (hereafter referred to as a FET) disposed on a silicon on insulator substrate (hereafter referred to as an SOI substrate) is used as, for example, a high-frequency switch or a power amplifier for a communication device such as a smartphone. When a FET is used as a high-frequency power amplifier, voltage tolerance is a challenge. A structure including a drift region to reduce gate-drain electric field concentration to thus increase voltage tolerance of a FET is known, as described, for example, in U.S. Patent Application Publication No. 2022/0059665. A MOSFET with this structure is referred to as, for example, an extended drain MOS (EDMOS).

As another structure to reduce gate-drain electric field concentration, a structure in which an electroconductive screen referred to as a field plate is disposed above a gate electrode is known as described, for example, in U.S. Patent Application Publication No. 2022/0059665. This structure is widely known in the field of FETs including a substrate formed from a material such as GaAs or GaN other than a SOI substrate. A typical field plate is connected to a region having a ground potential such as a source region.

### SUMMARY

A field plate is a technique for reducing gate-drain electric field concentration to improve voltage tolerance. However, when the field plate connected to a source region is disposed above the gate electrode, parasitic gate-source capacitance increases. The increase of parasitic gate-source capacitance causes a new challenge for a high-frequency FET.

The present disclosure aims to provide a semiconductor device including a field plate and capable of reducing parasitic gate-source capacitance.

An aspect of the present disclosure provides a semiconductor device that includes a field-effect transistor disposed on an insulating surface; an interlayer insulator film that covers the field-effect transistor; and an electroconductive field plate disposed on the interlayer insulator film. The field-effect transistor includes a source region with first electroconductivity, a body region with second electroconductivity, a drift region with the first electroconductivity, a drain region with the first electroconductivity, and a gate electrode. When the insulating surface is viewed in plan, the gate electrode has a shape elongated in a first direction, and the body region is disposed below the gate electrode to overlap the gate electrode. The source region and the drift region are disposed at positions to hold the body region therebetween in a second direction orthogonal to the first direction, and the drain region is disposed at a position farther than the drift region is when viewed from the body region. The field-effect transistor further includes a body contact region with the second electroconductivity that protrudes from a body contact connection portion, or a portion of the body region located closer to the source region, toward a portion where the source region is disposed. The field plate is electrically connected to the source region, and when the insulating surface is viewed in plan, the field plate extends from the source region at least to the drift region while intersecting the gate electrode, and has a shape not overlapping a first half line extending in the second direction from a middle point of the body contact connection portion toward the drain region.

The semiconductor device according to the present disclosure includes the field plate having a shape not overlapping the first half line, and thus can reduce an increase of parasitic gate-source capacitance.

### BRIEF DESCRIPTION OF THE DRAWINGS

FIG. 1 is a plan view of a semiconductor device according to a first embodiment;

FIG. 2A and FIG. 2B are cross-sectional views taken along dot-and-dash line 2A-2A and dot-and-dash line 2B-2B in FIG. 1;

FIG. 3 is a diagram describing a positional relationship of, for example, a body contact region, a gate electrode, and a field plate in a FET when viewed in plan;

FIG. 4A and FIG. 4B are cross-sectional views of a semiconductor device according to a first embodiment in a manufacturing process;

FIG. 5A and FIG. 5B are cross-sectional views of a semiconductor device according to the first embodiment in a manufacturing process;

FIG. 6 is a cross-sectional view of a semiconductor device according to the first embodiment in a manufacturing process;

FIG. 7A and FIG. 7B are cross-sectional views of a semiconductor device according to a modification example of the first embodiment;

FIG. 8 is a plan view of a semiconductor device according to another modification example of the first embodiment;

FIG. 9 is a plan view of a semiconductor device according to another modification example of the first embodiment;

FIG. 10 is a plan view of a semiconductor device according to another modification example of the first embodiment;

FIG. 11 is a plan view of a semiconductor device according to a second embodiment;

FIG. 12 is a cross-sectional view taken along dot-and-dash line 12-12 in FIG. 11;

FIG. 13 is a plan view of a semiconductor device according to a third embodiment; and

FIG. 14 is a diagram describing a positional relationship between components such as one gate electrode protrusion and a gate electrode and a field plate near the gate electrode protrusion in the semiconductor device according to the third embodiment when viewed in plan.

### DETAILED DESCRIPTION

### First Embodiment

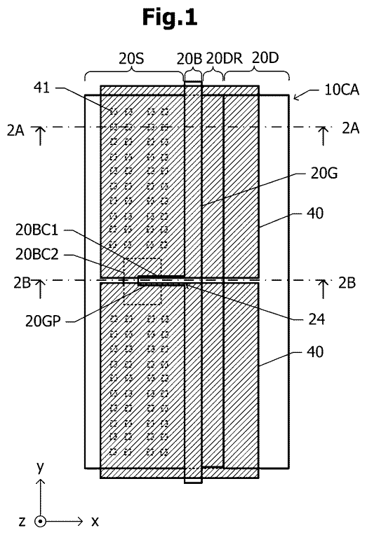

With reference to FIG. 1 to FIG. 6, a semiconductor device according to a first embodiment is described.

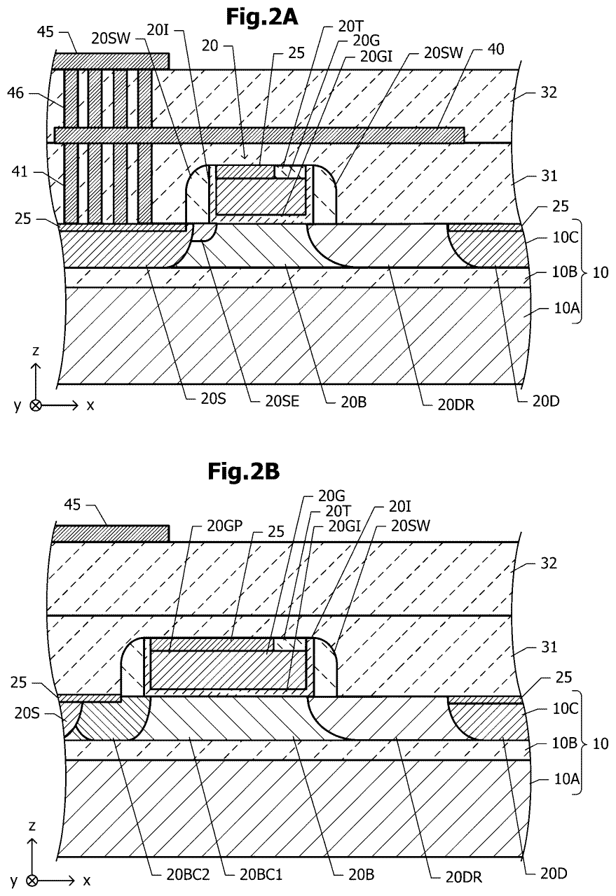

FIG. 1 is a plan view of the semiconductor device according to the first embodiment. In an active region 10CA of a device layer 10C (FIG. 2A and FIG. 2B) in an SOI substrate 10 described later, an N-type source region 20S, a P-type body region 20B, a N-type drift region 20DR, an N-type drain region 20D, and P-type body contact regions 20BC1 and 20BC2 forming a field-effect transistor (FET) 20 are formed. Donor concentration of the drift region 20DR is lower than donor concentration of the drain region 20D. Acceptor concentration of the body contact region 20BC1 is equal to acceptor concentration of the body region 20B. Acceptor concentration of the body contact region 20BC2 is higher than acceptor concentration of the body contact region 20BC1.

In a plan view, a gate electrode 20G is disposed to substantially overlap the body region 20B, and a gate electrode protrusion 20GP is disposed to substantially overlap the body contact region 20BC1. A width (dimension in a gate length direction) of the body region 20B may be smaller than a width (dimension in a gate length direction) of the gate electrode 20G.

The gate electrode 20G has a shape elongated in one direction in a plan view, and extends from one side to the opposite side of the rectangular active region 10CA. An xyz orthogonal coordinate system is defined on the plane of the device layer. In the xyz orthogonal coordinate system, the longitudinal direction of the gate electrode 20G is defined as a y direction, and a direction orthogonal to the y direction is defined as an x direction. The body region 20B has a shape elongated in the y direction, similar to the gate electrode 20G. The source region 20S and the drift region 20DR are disposed at positions to hold the body region 20B therebetween in the x direction. The drain region 20D is disposed at a position farther than the drift region 20DR is when viewed from the body region 20B, and is in contact with the drift region 20DR.

The body contact region 20BC1 protrudes from a body contact connection portion 24 or a portion of the body region 20B at an edge located closer to the source region 20S in a direction parallel to an x-axis, toward a portion where the source region 20S is disposed.

In a plan view, electroconductive field plates 40 extend from a position overlapping the source region 20S to a position intersecting the gate electrode 20G and the drift region 20DR and overlapping the drain region 20D. In FIG. 1, the field plates 40 are hatched. The field plates 40 are two plates separated by a straight line passing the body contact connection portion 24 and parallel to the x-axis.

In a plan view, the body contact region 20BC2 is disposed in the source region 20S. The body contact region 20BC2 is in contact with the body contact region 20BC1, and is electrically connected to the body region 20B with simply a P-type region interposed therebetween.

Multiple vias 41 are disposed in regions where the source region 20S and the field plates 40 overlap. The field plates 40 are electrically connected to the source region 20S with the multiple vias 41 interposed therebetween. Normally, the source region 20S has a ground potential. The field plates 40 thus also have a ground potential.

FIG. 2A and FIG. 2B are cross-sectional views taken along a dot-and-dash line 2A-2A and a dot-and-dash line 2B-2B in FIG. 1. The SOI substrate 10 includes a support substrate 10A, an embedded oxide film 10B, and a device layer 10C. The upper surface of the embedded oxide film 10B is formed from an insulating surface. The FET 20 is disposed on the insulating surface. For example, the support substrate 10A is formed from high-resistance Si, and the embedded oxide film 10B is formed from silicon oxide. The device layer 10C is formed from Si, and has a thickness of, for example, 75 nm.

The FET 20 includes the N-type source region 20S, the P-type body region 20B, the N-type drift region 20DR, the N-type drain region 20D, and the P-type body contact regions 20BC1 and 20BC2 disposed in the device layer 10C. The FET 20 also includes a gate insulator film 20GI, a gate electrode 20G, a gate electrode protrusion 20GP, a top-of-gate insulator film 20T, a side-of-gate insulator film 20I, and a side wall spacer 20SW disposed on the device layer.

The source region 20S, the drift region 20DR, and the drain region 20D extend from the upper surface of the device layer 10C to an interface between the device layer 10C and the embedded oxide film 10B. The body region 20B is disposed immediately below the gate electrode 20G. The source region 20S and the drift region 20DR hold the body region 20B therebetween in the x direction. An N-type source extension region 20SE is disposed between the source region 20S and the body region 20B in a top layer portion of the device layer 10C.

A silicide film 25 is disposed at a portion of the upper surface of the gate electrode 20G, and the remaining portion of the upper surface of the gate electrode 20G is covered with the top-of-gate insulator film 20T. The side surfaces of a structure including the gate electrode 20G, the gate electrode protrusion 20GP, the gate insulator film 20GI, the top-of-gate insulator film 20T, and the silicide film 25 on the gate electrode 20G are covered with the side-of-gate insulator film 20I, and the side surfaces of the side-of-gate insulator film 20I are covered with the side wall spacer 20SW. The gate electrode 20G and the gate electrode protrusion 20GP are formed from, for example, polysilicon. The gate insulator film 20GI is formed from, for example, silicon oxide, and has a thickness of approximately 6 nm. The side-of-gate insulator film 201 and the top-of-gate insulator film 20T are formed from, for example, silicon oxide, and the side wall spacer 20SW is formed from, for example, silicon nitride.

The drift region 20DR extends from a region outside the side wall spacer 20SW to the side surface of the gate electrode 20G through a portion below the side wall spacer 20SW. In the cross section illustrated in FIG. 2A, the source region 20S is disposed outside the side wall spacer 20SW, and the source extension region 20SE is disposed below the side wall spacer 20SW. The drift region 20DR may be disposed across the side surface of the gate electrode 20G to a portion immediately below the gate electrode 20G.

In the cross section illustrated in FIG. 2B, the body contact region 20BC2 extends from the region outside the side wall spacer 20SW to the end of the gate electrode protrusion 20GP through a portion below the side wall spacer 20SW. The body contact region 20BC2 is in contact with the body contact region 20BC1 immediately below the gate electrode protrusion 20GP, and is electrically connected to the body region 20B with the body contact region 20BC1 interposed therebetween.

The silicide film 25 is disposed on the upper surfaces of the source region 20S, the body contact region 20BC2, and the drain region 20D. An interlayer insulator film 31 in a first layer is disposed on the device layer 10C to cover the FET 20. In the interlayer insulator film 31, multiple vias 41 in the first layer connected to the silicide film 25 on the source region 20S are disposed. The field plates 40 are disposed on the interlayer insulator film 31. The field plates 40 are connected to the source region 20S and the body contact region 20BC2 with the multiple vias 41 and the silicide film 25 interposed therebetween. The field plates 40 extend from a portion above the source region 20S to a portion above the drain region 20D through a portion above the gate electrode 20G and the drift region 20DR.

In the example illustrated in FIG. 2A, the silicide film 25 disposed on the upper surface of the drain region 20D extends from an inner region of the upper surface of the drain region 20D to a boundary line between the drift region 20DR and the drain region 20D, but the silicide film 25 does not have to reach the boundary line between the drift region DR and the drain region 20D. More specifically, the silicide film 25 may be disposed in a part of a region in the upper surface of the drain region 20D.

An interlayer insulator film 32 in a second layer is disposed on the interlayer insulator film 31 and the field plates 40. Multiple vias 46 in the second layer are disposed in the interlayer insulator film 32. A source wire 45 is disposed on the interlayer insulator film 32. The source wire 45 is connected to the source region 20S with the multiple vias 46, the field plate 40, the multiple vias 41, and the silicide film 25 interposed therebetween.

The interlayer insulator films 31 and 32 are formed from an insulating inorganic material, such as silicon oxide or silicon nitride. The vias 41 and 46 are formed from, for example, a metal such as tungsten or copper, or an alloy containing any of these metals as a main material. The field plates 40 and the source wire 45 are formed from, for example, a metal such as tungsten, copper, or aluminum, or an alloy containing any of these metals as a main material.

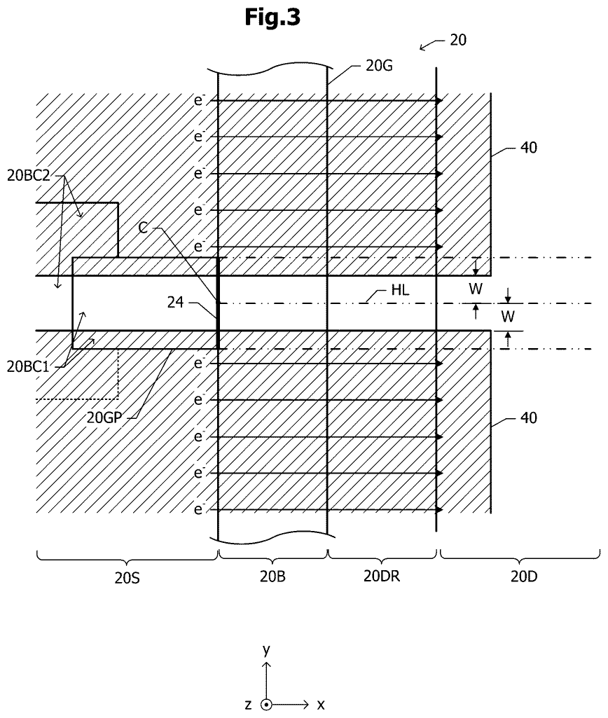

With reference to FIG. 3, the positional relationship between the body contact region 20BC1 and the field plates 40 when viewed in plan is described now.

FIG. 3 is a diagram describing positional relationship between portions of the FET 20, such as the body contact region 20BC1, the gate electrode 20G, and the field plates 40 when viewed in plan. In FIG. 3, the field plates 40 are hatched. The source region 20S, the body region 20B, the drift region 20DR, and the drain region 20D are arranged in this order in the x direction.

The gate electrode protrusion 20GP extends from a portion of the gate electrode 20G at the edge parallel to the y direction and closer to the source region 20S toward a region where the source region 20S is disposed. The body region 20B is disposed to substantially overlap the gate electrode 20G, and the body contact region 20BC1 is disposed to substantially overlap the gate electrode protrusion 20GP. More specifically, the body contact region 20BC1 extends from the body contact connection portion 24 or a portion of the edge of the body region 20B elongated in the y direction closer to the source region 20S toward a portion where the source region 20S is disposed. The body contact region 20BC1 is a region with the same conductive type as the body region 20B, and has a smaller dimension in the y direction than the body region 20B.

In FIG. 3, the body contact connection portion 24 is drawn with a bold solid line. In FIG. 3, the body contact connection portion 24 is drawn with a bold line segment, but the body contact connection portion 24 is not directly observed as a line segment. For example, the body contact connection portion 24 may be regarded as an imaginary boundary line between the body region 20B and the body contact region 20BC1. For example, the position of the body contact connection portion 24 in the x direction may be regarded as coinciding with the position in the x direction where the dimension in the y direction is changed in a p-type region forming the body region 20B and the body contact region 20BC1. The body contact connection portion 24 substantially coincides with the imaginary boundary line between the gate electrode 20G and the gate electrode protrusion 20GP.

The field plates 40 are disposed not to overlap with an imaginary half line HL, extending in a direction parallel to the x direction from a middle point C of the body contact connection portion 24 toward the drain region 20D. For example, the field plates 40 are two plates separated in the y direction at the position of the half line HL. The distance in the y direction from the half line HL to each of the field plates 40 is denoted with W.

When the FET 20 is operated, electrons e⁻ travel from the source region 20S to the drain region 20D through the body region 20B and the drift region 20DR. In terms of the range of the body contact connection portion 24 in the y direction, the source region 20S is not in contact with the body region 20B, and thus no electrons e are injected into the body region 20B.

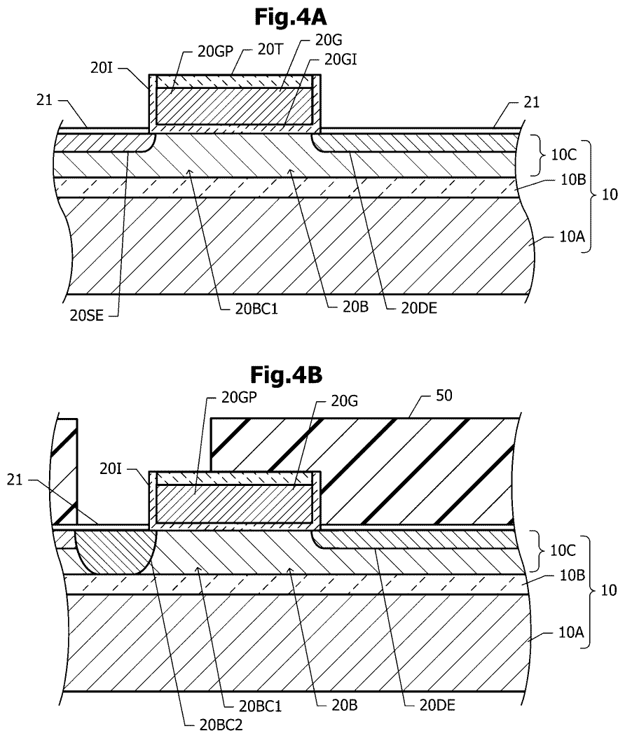

With reference to FIG. 4A to FIG. 6, a method for manufacturing the semiconductor device according to the first embodiment is described. FIG. 4A to FIG. 6 are cross-sectional views of the semiconductor device according to the first embodiment in the manufacturing process.

As illustrated in FIG. 4A, the SOI substrate 10 including the support substrate 10A, the embedded oxide film 10B, and the device layer 10C is prepared. After an element isolation region (not illustrated) is formed in the device layer 10C, a P-type dopant such as boron is injected into the device layer 10C to form the body region 20B and the body contact region 20BC1.

Thereafter, oxidation treatment is performed to form silicon oxide film to serve as the gate insulator film 20GI over the entire surface of the device layer 10C. A polysilicon film to serve as the gate electrode 20G and the gate electrode protrusion 20GP is then deposited, and an N-type dopant is injected into the polysilicon film. Thereafter, the silicon oxide film to serve as the top-of-gate insulator film 20T is deposited by, for example, chemical vapor deposition (CVD). The silicon oxide film, the polysilicon film, and the silicon oxide film are subjected to patterning. From these processes, the gate insulator film 20GI, the gate electrode 20G, the gate electrode protrusion 20GP, and the top-of-gate insulator film 20T are obtained. Thereafter, oxidation treatment is performed to form a through-oxide film 21 on the upper surface of the device layer 10C. At this time, the side-of-gate insulator film 201 is formed on the side surfaces of the gate electrode 20G.

Using the gate electrode 20G as a mask, a P-type dopant for forming a halo region (not illustrated) is injected, and an N-type dopant for forming the source extension region 20SE and a drain extension region 20DE is injected.

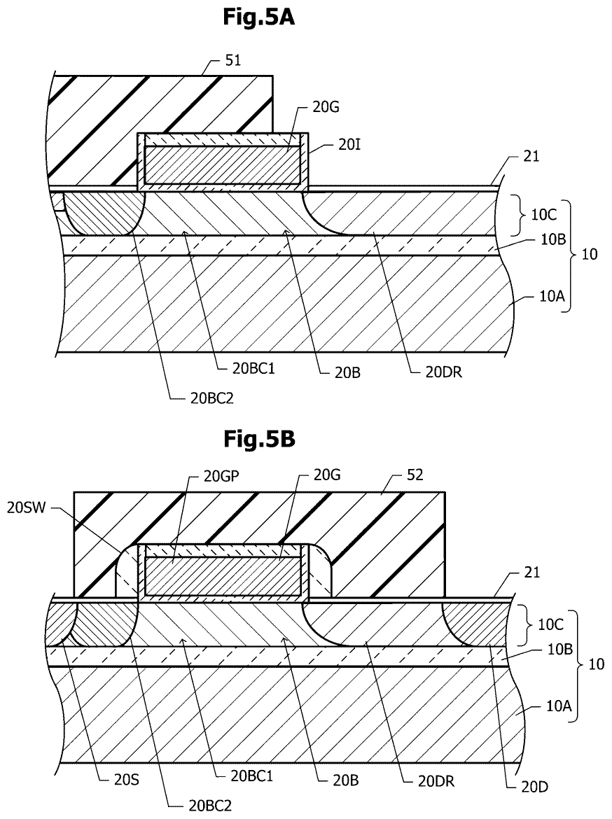

As illustrated in FIG. 4B, using a resist pattern 50 and the gate electrode protrusion 20GP as masks, a P-type dopant for forming the body contact region 20BC2 is injected. Moreover, as illustrated in FIG. 5A, using a resist pattern 51 and the gate electrode 20G as masks, an N-type dopant for forming the drift region 20DR is injected.

As illustrated in FIG. 5B, using a resist pattern 52 as a mask, an N-type dopant for forming the source region 20S and the drain region 20D is injected. At this time, in the cross section illustrated in FIG. 2A, the side wall spacer 20SW functions as a mask, and the source region 20S is thus formed outside the side wall spacer 20SW. Immediately below the side wall spacer 20SW closer to the source region 20S, the source extension region 20SE is formed with the N-type dopant injected in the process illustrated in FIG. 4A. The drain extension region 20DE (FIG. 4B) formed immediately below the side wall spacer 20SW of the drain region 20D umbrella is merged with the drift region 20DR formed in the process illustrated in FIG. 5A.

A dopant injected into the device layer 10C may be subjected to activation annealing every injection or collectively after all the amount of dopant is injected.

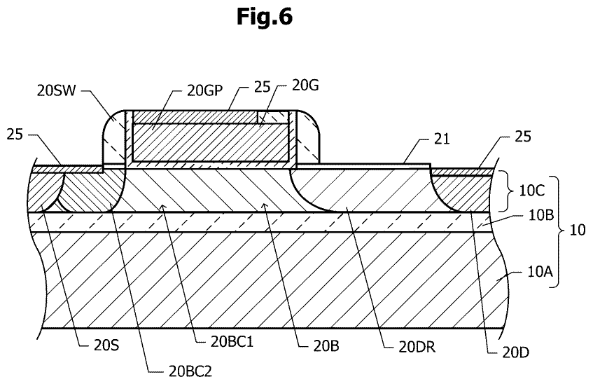

As illustrated in FIG. 6, the through-oxide film 21 (FIG. 5B) on the upper surfaces of the source region 20S, the body contact region 20BC2, and the drain region 20D is removed, and the top-of-gate insulator film 20T on a part of the region on the upper surface of the gate electrode 20G closer to the source region 20S is removed. Thereafter, the silicide film 25 is formed on the exposed upper surfaces of the source region 20S, the body contact region 20BC2, the drain region 20D, the gate electrode 20G, and the gate electrode protrusion 20GP. The silicide film 25 can be formed by forming a film of metal such as cobalt or titanium and then causing the metal film to react with silicon.

Thereafter, as illustrated in FIG. 2A and FIG. 2B, components such as the interlayer insulator film 31, the vias 41, the field plates 40, the interlayer insulator film 32, the vias 46, and the source wire 45 are formed.

Preferable effects of the first embodiment are described now.

In the first embodiment, the drift region 20DR and the field plates 40 can mitigate the gate-drain electric field concentration. In addition, due to impact ionization, a hole in an electron-hole pair generated near the boundary between the body region 20B and the drift region 20DR is transported to the ground through the body region 20B and the body contact regions 20BC1 and 20BC2. This structure can reduce accumulation of holes in the body region 20B.

The field plates 40 are not disposed at least in a portion of the body contact connection portion 24 (FIG. 1 and FIG. 3) in the y direction. More specifically, in a plan view, a part of the gate electrode 20G does not overlap the field plates 40. The parasitic gate-source capacitance is thus reduced as compared with a case where the entirety of the gate electrode 20G overlaps the field plates 40.

As an example index indicating the high-frequency performance of a FET, a current gain cutoff frequency ft is used. The current gain cutoff frequency ft is expressed by the formula below:

ft=gm/(2π(Cgs+Cgd)) (1)
In this formula, gm denotes transconductance, Cgs denotes parasitic gate-source capacitance, and Cgd denotes gate-drain parasitic capacitance. In the first embodiment, when the parasitic gate-source capacitance Cgs decreases, the reduction of the current gain cutoff frequency ft is reduced as expressed in formula (1).

In the range in the y direction in which the field plates 40 are not disposed, the effect of mitigating the gate-drain electric field concentration is reduced. However, as described above with reference to FIG. 3, in the range of the body contact connection portion 24 in the y direction, electrons e⁻ do not travel substantially, and impact ionization does not occur. Regardless of when a region where the field plates 40 are not disposed is generated within the range of the body contact connection portion 24, this structure does not reduce the impact-ionization reducing effect. As described above, the first embodiment can reduce parasitic gate-source capacitance Cgs without reducing the impact-ionization reducing the effect for the purpose of which the field plates 40 are disposed.

In the first embodiment, the field plates 40 are two separate plates even in the region where the field plates 40 and the drain region 20D overlap in a plan view. Thus, the source-drain parasitic capacitance Cds also decreases. When the FET 20 is used for a purpose for which the source-drain parasitic capacitance Cds adversely affects electric characteristics, the parasitic capacitance Cds decreases, and the decrease of electric characteristics can thus be reduced. For example, when the FET 20 is used for a high-voltage switch, output capacitance can be reduced.

The range in which the field plates 40 are to be disposed is described now.

To reduce impact ionization, as illustrated in FIG. 3, the field plates 40 are preferably disposed in the y direction within the range in which electrons e⁻ travel. More specifically, the field plates 40 are preferably disposed at least in a range in which a junction interface between the P-type body region 20B and the N-type source region 20S is disposed. Actually, as illustrated in FIG. 2A, the source extension region 20SE is disposed between the source region 20S and the body region 20B in the top layer portion of the device layer 10C. The junction interface between the P-type body region 20B and the N-type source region 20S is regarded as including a junction interface between the source extension region 20SE and the body region 20B.

When, in the y direction, the effect of an electron-hole pair resulting from impact ionization in the range near both ends of the body contact connection portion 24 is small, the structure not including the field plates 40 in the range near the body contact connection portion 24 in the junction interface between the source region 20S and the body region 20B may be employed. More specifically, the edges of the field plates 40 may be moved in a direction in which the distance W (FIG. 3) from the half line HL to each of the field plates 40 is increased. In this structure, the parasitic gate-source capacitance Cgs can be further reduced.

When the distance W (FIG. 3) from the half line HL to each of the field plates 40 is extremely short, the effect of reducing the parasitic gate-source capacitance Cgs is reduced. For example, preferably, to achieve a full effect of reducing the parasitic capacitance Cgs, the minimum value of the distance W in the y direction from the half line HL to each of the field plates 40 is preferably greater than or equal to ¼ of the dimension of the body contact connection portion 24 in the y direction.

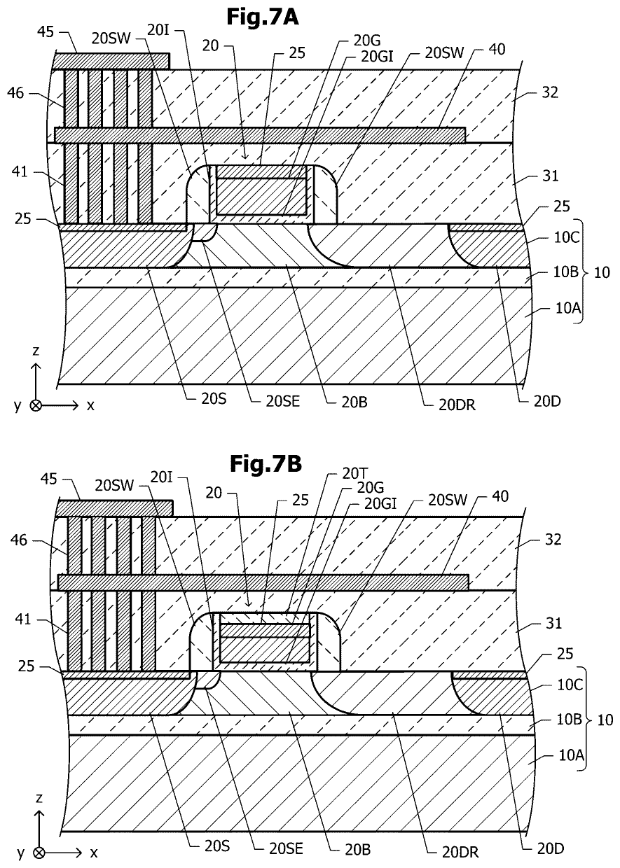

Subsequently, with reference to FIG. 7A and FIG. 7B, a semiconductor device according to a modification example of the first embodiment is described. FIG. 7A and FIG. 7B are cross-sectional views of a semiconductor device according to a modification example of the first embodiment. In the first embodiment (FIG. 2A), the silicide film 25 is disposed on a part of a region of the upper surface of the gate electrode 20G located closer to the source region 20S, and the top-of-gate insulator film 20T is disposed on the other part of the region.

In contrast, in a modification example illustrated in FIG. 7A, the silicide film 25 is disposed over the entire upper surface of the gate electrode 20G. Although not illustrated in the cross section in FIG. 7A, the silicide film 25 is also disposed over the entire upper surface of the gate electrode protrusion 20GP (FIG. 1).

In a modification example illustrated in FIG. 7B, similar to the modification example illustrated in FIG. 7A, the silicide film 25 is also disposed over the entire upper surface of the gate electrode 20G, and the top-of-gate insulator film 20T is also disposed over the entire upper surface of the silicide film 25.

As illustrated in FIG. 7A and FIG. 7B, disposing the silicide film 25 over the entire upper surface of the gate electrode 20G can further reduce the resistance of the gate electrode 20G.

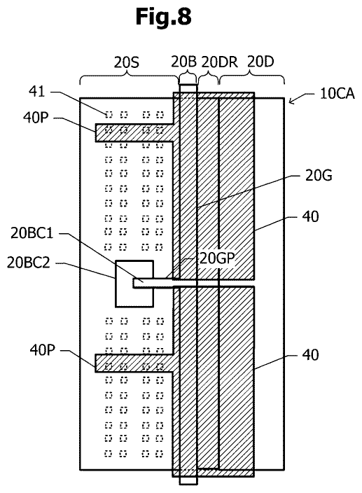

With reference to FIG. 8, a semiconductor device according to another modification example of the first embodiment is described now. FIG. 8 is a plan view of a semiconductor device according to a modification example of the first embodiment. In FIG. 8, the field plates 40 are hatched. In the first embodiment (FIG. 1), the field plates 40 have a rectangular shape when viewed in plan. More specifically, the dimension of the field plates 40 in the y direction is uniform irrespective of the position in the x direction. In contrast, in the field plates 40 in the modification example illustrated in FIG. 8, at least a portion overlapping the source region 20S has a smaller dimension in the y direction than a portion overlapping the gate electrode 20G. For example, each field plate 40 includes a field plate protrusion 40P that protrudes from the portion overlapping the gate electrode 20G toward a portion where the source region 20S is disposed.

At least one of the multiple vias 41 is disposed at a position overlapping the field plate protrusion 40P in a plan view, and the rest of the vias 41 are disposed in a region not overlapping the field plates 40. The vias 41 disposed in a region not overlapping the field plates 40 are connected to the vias 46 in the interlayer insulator film 32 in the second layer through an inner-layer land disposed in the same layer as the field plates 40 in the cross section illustrated in FIG. 2A.

As in the first embodiment, the modification example illustrated in FIG. 8 can also reduce the parasitic gate-source capacitance Cgs without reducing the effect of reducing impact ionization.

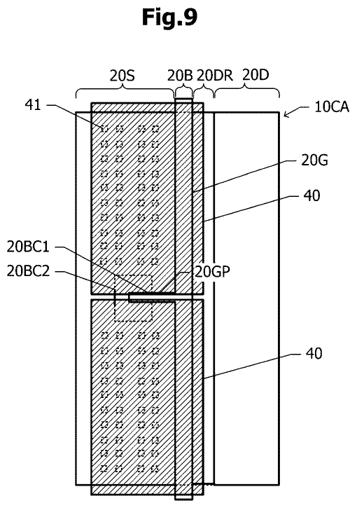

With reference to FIG. 9, a semiconductor device according to another modification example of the first embodiment is described now. FIG. 9 is a plan view of a semiconductor device according to the present modification example of the first embodiment. In FIG. 9, the field plates 40 are hatched. In the first embodiment (FIG. 1), the field plates 40 extend from the source region 20S to the drain region 20D through the body region 20B and the drift region 20DR in a plan view. In contrast, in the modification example illustrated in FIG. 9, the field plates 40 extend to a middle portion of the drift region 20DR without reaching the drain region 20D.

The structure of the present modification example can also mitigate electric field concentration between the gate electrode 20G and the drift region 20DR.

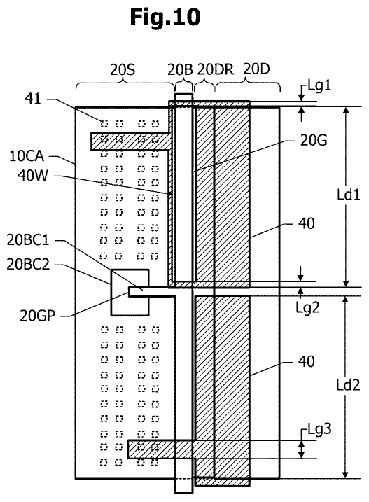

With reference to FIG. 10, a semiconductor device according to another modification example of the first embodiment is described now. FIG. 10 is a plan view of a semiconductor device according to the present modification example of the first embodiment. In FIG. 10, the field plates 40 are hatched. In the first embodiment (FIG. 1), the dimension of a portion of each field plate 40 in the y direction overlapping the drift region 20DR is the same as the dimension of a portion of the field plate 40 in the y direction overlapping the gate electrode 20G in a plan view.

In contrast, in the modification example illustrated in FIG. 10, a portion of each field plate 40 overlapping the gate electrode 20G has a smaller dimension in the y direction than a portion of the field plate 40 overlapping the drift region 20DR in a plan view. When each field plate 40 includes multiple “overlapping portions”, “the dimension of the overlapping portions in the y direction” indicates the sum of the dimension of the overlapping portions in the y direction.

For example, in FIG. 10, one of the field plates 40 (upper one in FIG. 10) has an opening 40W that overlaps a part of the gate electrode 20G. This field plate 40 overlaps the gate electrode 20G at two portions. The dimensions of the two overlapping portions in the y direction are denoted with Lg1 and Lg2. The dimension of a portion in the y direction where the field plate 40 and the drift region DR overlap is denoted with Ld1.

The other (lower one in FIG. 10) field plate 40 overlaps the gate electrode 20G at one portion. The dimension of this overlapping portion in the y direction is denoted with Lg3. The dimension of a portion in the y direction where the field plate 40 and the drift region DR overlap is denoted with Ld2. Thus, the relationship described below is satisfied:

Lg1+Lg2<Ld1,

Lg3<Ld2, and

Lg1+Lg2+Lg3<Ld1+Ld2 (2)

As in the modification example illustrated in FIG. 10, when the dimension of a portion of each field plate 40 in the y direction overlapping the gate electrode 20G is smaller than the dimension of a portion of the field plate 40 in the y direction overlapping the drift region 20DR in a plan view, the effect of reducing the parasitic gate-source capacitance Cgs can be enhanced.

Although the semiconductor device according to the first embodiment includes an N-channel FET 20, the semiconductor device may include a P-channel FET, or both an N-channel FET and a P-channel FET.

In the first embodiment illustrated in FIG. 2B, the position of the boundary between the body contact region 20BC1 and the body contact region 20BC2 in the x direction is substantially aligned with the position of the end (left end in FIG. 2B) of the gate electrode protrusion 20GP, but the positions may be misaligned with each other. For example, when ion is injected to form the body contact region 20BC2 before the gate electrode 20G and the gate electrode protrusion 20GP are formed, a structure where the boundary between the body contact region 20BC2 and the body contact region 20BC1 is positioned at the middle point of the gate electrode protrusion 20GP in the x direction is obtained in FIG. 1.

### Second Embodiment

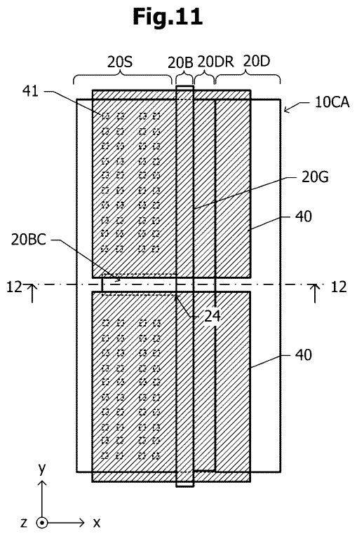

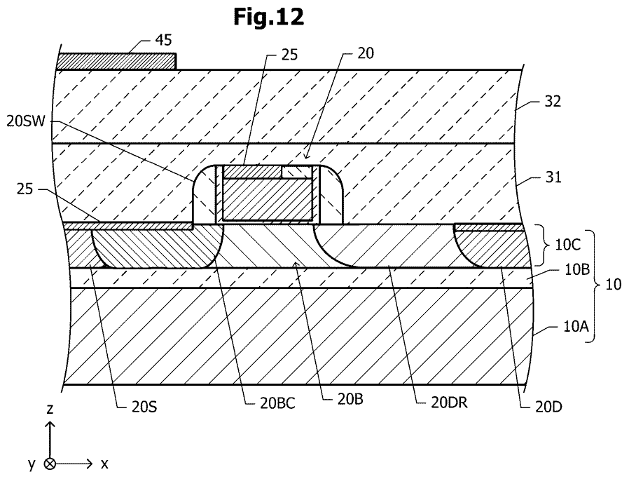

With reference to FIG. 11 and FIG. 12, a semiconductor device according to a second embodiment is described now. The components the same as those in the semiconductor device according to the first embodiment described with reference to FIG. 1 to FIG. 6 are not described below.

FIG. 11 is a plan view of the semiconductor device according to the second embodiment. In FIG. 11, the field plates 40 are hatched. The semiconductor device according to the first embodiment (FIG. 1) includes the gate electrode protrusion 20GP protruding from the gate electrode 20G toward the source region 20S. In contrast, the semiconductor device according to the second embodiment does not include the gate electrode protrusion 20GP.

A body contact region 20BC is disposed to be in contact with the edge of the gate electrode 20G closer to the source region 20S in a plan view. For example, acceptor concentration of the body contact region 20BC is the same as acceptor concentration of the body contact region 20BC2 (FIG. 1) in the semiconductor device according to the first embodiment. P-type dopant injection for forming the body contact region 20BC is performed in place of P-type dopant injection for forming the body contact region 20BC2 (FIG. 4B) in the semiconductor device according to the first embodiment.

In the second embodiment, the boundary line between the body region 20B and the body contact region 20BC in a plan view forms the body contact connection portion 24.

FIG. 12 is a cross-sectional view taken along dot-and-dash line 12-12 in FIG. 11. The body contact region 20BC extends to a portion immediately below the side wall spacer 20SW to be in contact with the body region 20B. In the process illustrated in FIG. 4A, an N-type dopant to form the source extension region 20SE is injected to a portion immediately below the side wall spacer 20SW. Doping concentration of the P-type dopant is much higher than doping concentration of the N-type dopant, and the region immediately below the side wall spacer 20SW is thus formed into a P-type region.

In the first embodiment (FIG. 2B), the body contact region 20BC2 having higher acceptor concentration than the body region 20B is connected to the body region 20B through the body contact region 20BC1 having the same acceptor concentration as the body region 20B. In contrast, in the second embodiment, the body contact region 20BC having higher acceptor concentration than the body region 20B is in direct contact with the body region 20B.

Preferable effects of the second embodiment are described now.

Similar to the semiconductor device according to the first embodiment, the semiconductor device according to the second embodiment can reduce the parasitic gate-source capacitance Cgs without reducing the effect of reducing impact ionization. Preferable positional relationship between the body contact connection portion 24 and the field plates 40 when viewed in plan is the same as that in the first embodiment.

### Third Embodiment

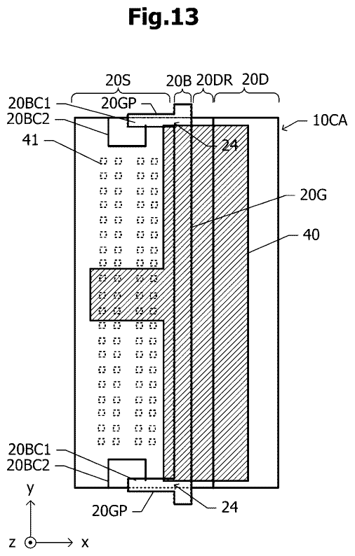

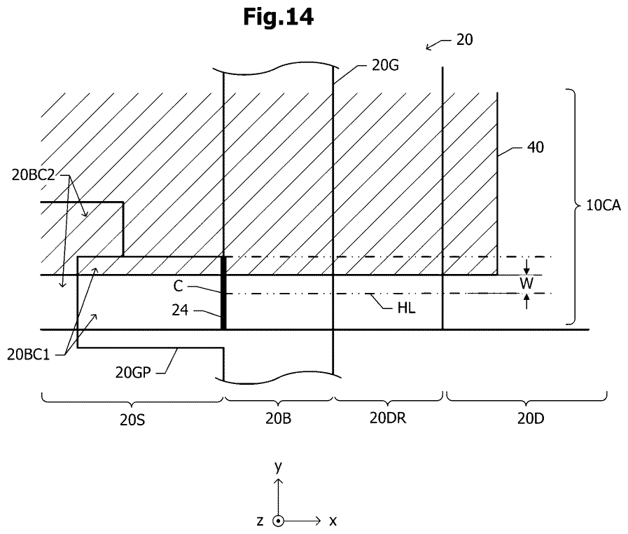

With reference to FIG. 13 and FIG. 14, a semiconductor device according to a third embodiment is described now. The components the same as those in the semiconductor device according to the first embodiment described with reference to FIG. 1 to FIG. 6 are not described below.

FIG. 13 is a plan view of the semiconductor device according to the third embodiment. In FIG. 13, the field plates 40 are hatched. In the first embodiment (FIG. 1), one gate electrode protrusion 20GP is disposed at substantially the center of the gate electrode 20G in the y direction. In contrast, in the third embodiment, gate electrode protrusions 20GP are disposed near both ends of the gate electrode 20G in the y direction. The two gate electrode protrusions 20GP are disposed at positions overlapping the edge of the active region 10CA.

FIG. 14 is a diagram illustrating the positional relationship between components including one gate electrode protrusion 20GP, the gate electrode 20G near the gate electrode protrusion 20GP, and the field plate 40 when viewed in plan. In FIG. 14, the field plate 40 is hatched. In the first embodiment (FIG. 3), the body contact region 20BC1 is disposed over substantially the entirety of the gate electrode protrusion 20GP in a plan view. In contrast, in the third embodiment, the body contact region 20BC1 is disposed over substantially the entirety of a portion of the region in which the gate electrode protrusion 20GP is disposed within the active region 10CA in a plan view.

Thus, the dimension of the body contact connection portion 24 in the y direction is smaller than the dimension of the gate electrode protrusion 20GP in the y direction. The body contact connection portion 24 is connected to the edge of the active region 10CA at a first end portion. As in the first embodiment (FIG. 3), the field plate 40 does not overlap the half line HL extending in a direction parallel to the x direction from the middle point C of the body contact connection portion 24 toward the drain region 20D. The field plate 40 is disposed simply on one side (closer to the center portion of the active region 10CA) of the half line HL. In the first embodiment (FIG. 1), the field plates 40 are two separate plates. In the third embodiment, however, the field plate 40 is formed from a single continuous unit.

As in the case of the first embodiment (FIG. 3), the distance W from the half line HL to the field plate 40 in the y direction is preferably greater than or equal to ¼ of the dimension of the body contact connection portion 24 in the y direction.

Preferable effects of the third embodiment are described now.

Similar to the semiconductor device according to the first embodiment, the semiconductor device according to the third embodiment can reduce the parasitic gate-source capacitance Cgs without reducing the effect of reducing impact ionization.

The embodiments described above are provided by way of example only, and components disclosed in different embodiments may be partially substituted or combined. The same or similar effects achieved by similar configurations among the embodiments will not be described redundantly for each embodiment. The present disclosure is not limited to the embodiments described above. For example, various modifications, improvements, and combinations will be apparent to those skilled in the art.

The following is based on the embodiments described herein.

<1> A semiconductor device, comprising a field-effect transistor disposed on an insulating surface; an interlayer insulator film that covers the field-effect transistor; and an electroconductive field plate disposed on the interlayer insulator film. The field-effect transistor includes a source region with first electroconductivity, a body region with second electroconductivity, a drift region with the first electroconductivity, a drain region with the first electroconductivity, and a gate electrode. When the insulating surface is viewed in plan, the gate electrode has a shape elongated in a first direction, and the body region is disposed below the gate electrode to overlap the gate electrode. The source region and the drift region are disposed at positions to hold the body region therebetween in a second direction orthogonal to the first direction, and the drain region is disposed at a position farther than the drift region is when viewed from the body region. The field-effect transistor further includes a body contact region with the second electroconductivity that protrudes from a body contact connection portion, or a portion of an edge of the body region located closer to the source region, toward a portion where the source region is disposed. The field plate is electrically connected to the source region, and when the insulating surface is viewed in plan, the field plate extends from the source region at least to the drift region while intersecting the gate electrode, and has a shape not overlapping a first half line extending in the second direction from a middle point of the body contact connection portion toward the drain region.

<2> The semiconductor device according to <1>, wherein when the insulating surface is viewed in plan, the field plate extends at least to a boundary line between the drift region and the drain region.

<3> The semiconductor device according to <1> or <2>, wherein the field plate is disposed, in the first direction, at least in a range in which a junction interface between the body region and the source region is disposed.

<4> The semiconductor device according to any one of <1> to <3>, wherein a distance in the first direction from the first half line to the field plate is greater than or equal to ¼ of a dimension of the body contact connection portion in the first direction.

<5> The semiconductor device according to any one of <1> to <4>, wherein the body contact connection portion is disposed between two ends of the body region in the first direction, and the field plate includes at least two portions divided in the first direction at a position of the first half line.

6> The semiconductor device according to any one of <1> to <4>, wherein the body contact region is disposed at each of two ends of the body region in the first direction, and the field plate is formed from a single continuous pattern.

<7> The semiconductor device according to any one of <1> to <6>, wherein when the insulating surface is viewed in plan, a portion where the field plate and the gate electrode overlap has a smaller dimension in the first direction than a portion where the field plate and the drift region overlap.

What is claimed is:

1. A semiconductor device, comprising:
a field-effect transistor on an insulating surface;
an interlayer insulator film that covers the field-effect transistor; and
an electroconductive field plate on the interlayer insulator film,
wherein
the field-effect transistor includes a source region with first electroconductivity, a body region with second electroconductivity, a drift region with the first electroconductivity, a drain region with the first electroconductivity, and a gate electrode,
when the insulating surface is viewed in plan, the gate electrode has a shape elongated in a first direction, and the body region is below the gate electrode to overlap the gate electrode,
the source region and the drift region are at positions to hold the body region therebetween in a second direction orthogonal to the first direction, and the drain region is at a position farther than the drift region is when viewed from the body region,
the field-effect transistor further includes a body contact region with the second electroconductivity that protrudes from a body contact connection portion, or a portion of an edge of the body region located closer to the source region, toward a portion where the source region is disposed,
the field plate is electrically connected to the source region, and
when the insulating surface is viewed in plan, the field plate extends from the source region at least to the drift region while intersecting the gate electrode, and has a shape not overlapping a first half line extending in the second direction from a middle point of the body contact connection portion toward the drain region.

2. The semiconductor device according to claim 1, wherein
when the insulating surface is viewed in plan, the field plate extends at least to a boundary line between the drift region and the drain region.

3. The semiconductor device according to claim 1, wherein
the field plate is disposed, in the first direction, at least in a range in which a junction interface between the body region and the source region is disposed.

4. The semiconductor device according to claim 1, wherein
a distance in the first direction from the first half line to the field plate is greater than or equal to ¼ of a dimension of the body contact connection portion in the first direction.

5. The semiconductor device according to claim 1, wherein
the body contact connection portion is between two ends of the body region in the first direction, and
the field plate includes at least two portions divided in the first direction at a position of the first half line.

6. The semiconductor device according to claim 1, wherein
the body contact region is at each of two ends of the body region in the first direction, and
the field plate is a single continuous pattern.

7. The semiconductor device according to claim 1, wherein
when the insulating surface is viewed in plan, a portion where the field plate and the gate electrode overlap has a smaller dimension in the first direction than a portion where the field plate and the drift region overlap.

8. The semiconductor device according to claim 2, wherein
the field plate is disposed, in the first direction, at least in a range in which a junction interface between the body region and the source region is disposed.

9. The semiconductor device according to claim 2, wherein
a distance in the first direction from the first half line to the field plate is greater than or equal to ¼ of a dimension of the body contact connection portion in the first direction.

10. The semiconductor device according to claim 3, wherein
a distance in the first direction from the first half line to the field plate is greater than or equal to ¼ of a dimension of the body contact connection portion in the first direction.

11. The semiconductor device according to claim 2, wherein
the body contact connection portion is between two ends of the body region in the first direction, and
the field plate includes at least two portions divided in the first direction at a position of the first half line.

12. The semiconductor device according to claim 3, wherein
the body contact connection portion is between two ends of the body region in the first direction, and
the field plate includes at least two portions divided in the first direction at a position of the first half line.

13. The semiconductor device according to claim 4, wherein
the body contact connection portion is between two ends of the body region in the first direction, and
the field plate includes at least two portions divided in the first direction at a position of the first half line.

14. The semiconductor device according to claim 2, wherein
the body contact region is at each of two ends of the body region in the first direction, and
the field plate is a single continuous pattern.

15. The semiconductor device according to claim 3, wherein
the body contact region is at each of two ends of the body region in the first direction, and
the field plate is a single continuous pattern.

16. The semiconductor device according to claim 4, wherein
the body contact region is at each of two ends of the body region in the first direction, and
the field plate is a single continuous pattern.

17. The semiconductor device according to claim 5, wherein
the body contact region is at each of two ends of the body region in the first direction, and
the field plate is a single continuous pattern.

18. The semiconductor device according to claim 2, wherein
when the insulating surface is viewed in plan, a portion where the field plate and the gate electrode overlap has a smaller dimension in the first direction than a portion where the field plate and the drift region overlap.

19. The semiconductor device according to claim 3, wherein
when the insulating surface is viewed in plan, a portion where the field plate and the gate electrode overlap has a smaller dimension in the first direction than a portion where the field plate and the drift region overlap.

20. The semiconductor device according to claim 4, wherein
when the insulating surface is viewed in plan, a portion where the field plate and the gate electrode overlap has a smaller dimension in the first direction than a portion where the field plate and the drift region overlap.
